(19) United States
(12) Patent Application Publication
(10) Pub. No.: US 2026/0092360 A1
(43) Pub. Date: Apr. 2, 2026

(54) CYCLICAL DEPOSITION METHOD INCLUDING TREATMENT STEP AND APPARATUS FOR SAME

(71) Applicant: ASM IP Holding B.V., Almere (NL)

(72) Inventors: Kai Matsuhisa, Tokyo (JP); Satomi Ota, Tokyo (JP); Trigagema Gama, Yamato-shi (JP); Anhtuan Phan, Tokyo (JP)

(21) Appl. No.: 19/338,804

(22) Filed: Sep. 24, 2025

Related U.S. Application Data
(60) Provisional application No. 63/700,509, filed on Sep. 27, 2024.

(51) Int. Cl. C23C 16/04; C23C 16/24; C23C 16/40; C23C 16/455; C23C 16/46; C23C 16/52; H01J 37/32; H01L 21/02

(52) U.S. Cl. CPC C23C 16/045; C23C 16/24; C23C 16/401; C23C 16/45542; C23C 16/45544; C23C 16/46; C23C 16/52; H01J 37/32449; H10P 14/6339; H10P 14/69215; H01J 2237/332; H10P 14/6927

(57) ABSTRACT

A method and apparatus for depositing a material on a surface of a substrate are disclosed. The method can include a treatment step to suppress a rate of material deposition on the surface of the substrate. The method can result in higher-quality deposited material. Additionally or alternatively, the method can be used to fill a gap within the surface of the substrate with reduced or no seam formation.

### CROSS-REFERENCE TO RELATED APPLICATIONS

This application claims priority to U.S. Provisional Patent Application Ser. No. 63/700,509 filed Sep. 27, 2024 titled CYCLICAL DEPOSITION METHOD INCLUDING TREATMENT STEP AND APPARATUS FOR SAME, the disclosure of which is hereby incorporated by reference in its entirety.

### FIELD OF INVENTION

The present disclosure generally relates to methods and apparatus for manufacturing electronic devices. More particularly, the disclosure relates to methods and apparatus for depositing films during the formation of the electronic devices.

### BACKGROUND OF THE DISCLOSURE

During manufacturing of electronic devices, such as integrated circuits, films or layers of material are often deposited onto a surface of a substrate. Such films can be patterned and etched to form desired structures. Additionally or alternatively, films can be deposited to fill gaps or recesses, such as vias, trenches, or spaces between fins, on a surface of a substrate.

In the case of filling a gap, a typical film deposition process may be subjected to drawbacks, including void formation in the gap. Voids may be formed when the deposited material forms a constriction near a top of the gap before the gap is completely filled with the deposited material. Such voids may compromise device isolation of the devices of an integrated circuit (IC) as well as the overall structural integrity of the IC. Unfortunately, preventing void formation during gap fill may place size constraints on the gaps, which may limit device packing density of the IC.

Void formation may be mitigated by decreasing gap depth and/or tapering gap sidewalls, so that the openings of the gap are wider at the top than at the bottom of the gap. A trade off in decreasing the gap depth may be reducing the effectiveness of the device isolation, while the larger top openings of gaps with tapering sidewalls may use up additional IC real estate. Such problems can become increasingly problematic when attempting to reduce device dimensions. Furthermore, it may be generally desirable to form films of relatively high quality—e.g., films having relatively high etch rates in, for example, hydrofluoric and/or phosphoric acid. Accordingly, improved methods and apparatus for forming high-quality films and/or for filling a gap are desired.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter

Various embodiments of the present disclosure relate to method of filling a gap performing a deposition process and to apparatus for depositing the material for filling the gap. While the ways in which various embodiments of the present disclosure address drawbacks of prior methods are discussed in more detail below, in general, exemplary embodiments of the disclosure provide improved methods and apparatus for depositing high quality material and/or to methods for seamlessly filling high aspect ratio gaps with the deposited material. As set forth in more detail below, exemplary methods can include a step of treating a surface of a substrate to inhibit or slow a growth rate of the deposited material. The growth-rate inhibition is thought to improve a quality of the deposited material and/or to facilitate seamless filling of a gap with the deposited material. Additionally, high-quality material can be deposited, without post-treatment annealing of the deposited material that is otherwise often performed to improve the quality of the deposited material.

In accordance with at least one embodiment of the disclosure, a method for filling a gap, the method comprising the steps of: providing the substrate with a gap in a reaction chamber; forming first active species from a first reactant for forming an inhibition layer in a vicinity of a top of the gap; and performing one or more deposition cycles to deposit a material into the gap. Each deposition cycle comprises introducing a second reactant to the reaction chamber, wherein the second reactant reacts with the surface of the substrate to form a chemisorbed layer in the gap; and forming a second active species from a third reactant that reacts with the chemisorbed layer to form a deposited layer. The second active species is formed providing pulsed plasma power to an electrode for a plasma power period to form a plasma within the reaction chamber. The reaction of the second reactant in the vicinity of the top of the gap is at least partially inhibited by the inhibition layer. A ratio of a number of steps of forming first active species and a number of deposition cycles ranges from about 1:1 to about 1:10. In accordance with various aspects, a flow of the first reactant is continuous during and through the step of forming first active species and the step of performing one or more deposition cycles. In accordance with further aspects, the inert gas can be provided continuously during and through the steps of forming first active species and performing one or more deposition cycles.

According to a further embodiment, there is provided a semiconductor processing apparatus to provide, for example, an improved or at least an alternative deposition method, such as a method described herein. In accordance with at least one embodiment of the disclosure, a semiconductor processing apparatus includes one or more reaction chambers for accommodating a substrate; a first source for a first reactant in gas communication via a first valve with one of the reaction chambers; a second source for a second reactant in gas communication via a second valve with one of the reaction chambers; a third source for a third reactant in gas communication via a third valve with one of the reaction chambers; and a controller operably connected to the first, second, and third gas valves and configured and programmed to control: forming first active species from a first reactant for forming an inhibition layer in a vicinity of a top of the gap; and performing one or more deposition cycles to deposit a material into the gap. Each deposition cycle comprises introducing a second reactant to the reaction chamber, wherein the second reactant reacts with the surface of the substrate to form a chemisorbed layer in the gap; and forming a second active species from a third reactant that reacts with the chemisorbed layer to form a deposited layer. The second active species is formed providing pulsed plasma power to an electrode for a plasma power period to form a plasma within the reaction chamber. The reaction of the second reactant in the vicinity of the top of the gap is at least partially inhibited by the inhibition layer. A ratio of a number of steps of forming first active species and a number of deposition cycles ranges from about 1:1 to about 1:10. The controller can be further configured to provide inert gas continuously during the steps of forming first active species and performing one or more deposition cycles. Additionally or alternatively, the controller can be configured to provide a flow of the first reactant continuously during the step of forming first active species and the step of performing one or more deposition cycles. The controller can additionally or alternatively be configured to provide a flow of the third reactant (e.g., continuously) from a treatment purge step and through the step of performing one or more deposition cycles. Further, the apparatus as described herein can be used to perform one or more methods as described herein.

In accordance with yet further exemplary embodiments of the disclosure, a semiconductor structure can be formed using a method and/or an apparatus as described herein.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein. These and other embodiments will become readily apparent to those skilled in the art from the following detailed description of certain embodiments having reference to the figures, the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrated a method for depositing a material in a gap in accordance with at least one embodiment of the disclosure.

FIG. 2 illustrates a process sequence in accordance with at least one embodiment of the present disclosure.

FIG. 3 illustrates a process sequence in accordance with at least one embodiment of the present disclosure.

FIG. 4A illustrates schematic representation of a PEALD (plasma-enhanced atomic layer deposition) apparatus suitable for filling a gap in accordance with at least one embodiment of the present disclosure.

FIG. 4B illustrates a schematic representation of a precursor supply system using a flow-pass system (FPS) usable in accordance with at least one embodiment of the present disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

Exemplary embodiments of the disclosure can be used to deposit material on a surface of a substrate. For example, exemplary methods and apparatus can be used to fill gaps, such as trenches, vias, and/or areas between fins, on a surface of a substrate. In accordance with examples of the disclosure, a treatment step is used to suppress a growth rate of a subsequently deposited film—e.g., by removal of hydrogen and/or hydroxyl groups from a surface of the substrate. It is thought that the suppression of the growth rate contributes to filling a gap, while mitigating or eliminating void and/or seam formation within the gap. In addition, the suppression of growth rate can contribute to deposition of higher-quality films, compared to films deposited using conventional techniques. Further, the methods and apparatus can be used to deposit high-quality material, without a need for further post treatment, such as annealing, of the material. Although methods described herein can be configured to reduce a deposition growth rate, as discussed in more detail below, various process steps can be configured, such that an overall process time to deposit the film is kept relatively low.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

By way of examples, a substrate can include a material that includes hydrogen and/or hydroxyl group terminated sites. For example, the substrate can be or include silicon and/or silicon oxide with hydroxyl terminated groups and/or hydrogen terminated groups.

As used herein, the term “reactant” or “precursor” can be used interchangeably and refer generally to at least one compound that participates in deposition reaction to deposit a layer on a substrate.

In some embodiments, “layer” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation process or sequence, and/or functions or purposes of the adjacent films or layers.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as a rare gas. In some cases, the term “precursor” can refer to a compound that participates in the chemical reaction that produces another compound, and particularly to a compound that constitutes a film matrix or a main skeleton of a film; the term “reactant” can be used interchangeably with the term precursor. The term “inert gas” can refer to a gas that does not take part in a chemical reaction and/or does not become a part of a film matrix to an appreciable extent. Exemplary inert gases include noble gasses such as helium, argon, and any combination thereof. In some cases, an inert gas can include nitrogen and/or hydrogen. Purge gasses can comprise inert gasses.

“At least one”, “one or more”, and “and/or” are open-ended expressions that are both conjunctive and disjunctive in operation. For example, each of the expressions “at least one of A, B, and C”, “at least one of A, B, or C”, “one or more of A, B, and C”, “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X1-Xn, Y1-Ym, and Z1-Zo, the phrase is intended to refer to a single element selected from X, Y, and Z, a combination of elements selected from the same class (e.g., X1 and X2) as well as a combination of elements selected from two or more classes (e.g., Y1 and Zo).

As used herein, the term atomic layer deposition (ALD) may refer to a vapor deposition process in which deposition cycles, typically a plurality of consecutive deposition cycles, are conducted in a process chamber. Generally, during each cycle, a precursor is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor(s)/reactive gas(es), and purge (e.g., inert carrier) gas(es). The terms reactant and precursor can be used interchangeably.

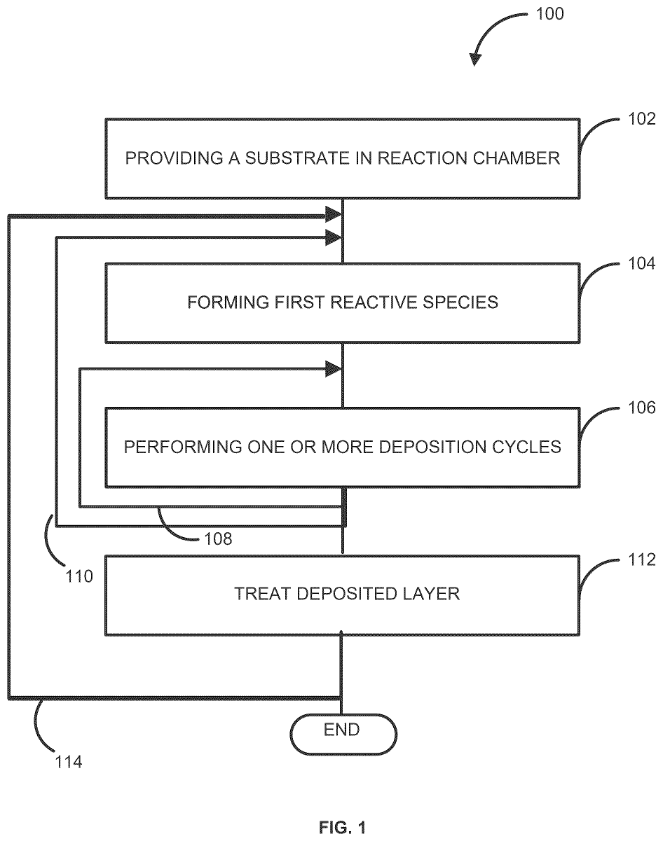

Turning now to the figures, FIG. 1 illustrates a method of filling a gap in a substrate with a material 100 in accordance with at least one embodiment of the disclosure. Method of depositing a material on a surface of a substrate 100 can be used to, for example, fill one or more gaps, sometimes referred to as recesses or features, created during manufacturing of a structure—e.g., structures formed during the manufacture of electronic devices. An opening at a top of a gap may be, for example, less than 40 or even 20 nm wide; a depth of the gap may be more than 40, 100, 200 or even 400 nm. An aspect ratio of the gaps can range from, for example, about 5:1 to about 30:1.

Method of depositing a material into a gap on a surface of a substrate 100 can be a cyclic deposition process, such as an ALD process. In the illustrated example, method of depositing a material on a surface of a substrate 100 includes the steps of providing the substrate in a reaction chamber (step 102), forming first reactive species (step 104), and performing one or more deposition cycles (step 106). As illustrated, step 106 can be repeated a number of times, as illustrated by loop 108, prior to ending method of depositing a material on a surface of a substrate 100. Optionally, the method can include a treatment step 112 where the deposited layer is treated. Additionally or alternatively, steps 104 and 106 can be repeated (with step 106 optionally additionally repeated), as illustrated by loop 110. Additionally or alternatively, steps 104, 106 and 112 can be repeated as illustrated by loop 114. A ratio of step 104 (also referred to herein as a treatment step) and step 106 (also referred to herein as a deposition cycle) can be, for example, 1:1, 1:3, 1:5, 1:10 and any range between such values.

Providing the substrate in a reaction chamber step 102 includes providing a substrate to a reaction chamber for processing in accordance with method 100. By way of example, a substrate can include a layer of or a layer including silicon and having at least one gap formed therein. Additionally or alternatively, the substrate can include a layer of, for example, silicon oxide or photoresist.

During step 102, the substrate can be brought to a desired temperature for subsequent processing using, for example, a substrate heater and/or radiative or other heaters. A temperature during steps 102-106 can be less than 600° C. or less than 550° C., or less than 500° C. or 450° C. or less than 400° C., or range from about 20° C. to about 600° C. or about 50° C. to about 550° C. A pressure within the reaction chamber during steps 102-106 can be from about 1 Torr to about 5 Torr or about 2 Torr to about 4 Torr.

During step 104, a first active species from a first reactant is formed. The first reactive species can be used to modify a surface of a substrate—e.g., to slow a growth rate of a material deposited during step 106. For example, the first active species can be used to passivate otherwise active/reactive sites on the surface of a substrate. As a result, a growth per cycle of deposited material on the surface of the substrate (e.g., a surface of a gap formed within the substrate) can be reduced, compared to a growth per cycle of deposited material on a surface (e.g., another portion of the surface or another substrate surface) that has not been treated.

The active species can be formed using an in-situ or remote plasma. A plasma power during step 104 can range from about 100 W to about 1500 W or about 150 W to about 1000 W or about 400 W to about 900 W. The plasma can be formed using a pulse time of and/or an on time for the plasma during step 104 can range from about 1 seconds to about 20 (e.g., 10) seconds or about 1 seconds to about 15 (e.g., 5) seconds or about 8 seconds to about 12 seconds or about 3 seconds to about 7 seconds.

In accordance with examples of the disclosure, the first reactant can comprise nitrogen or a gas comprising nitrogen. In accordance with further examples, the first reactant can include one or more of nitrogen, NH₃, NF₃, NO, N₂O, NO₂ and N₂H₄, or derivatives thereof.

Step 104 can include a first reactant purge sub step. During the first reactant purge sub step, excess reactant(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 500 sccm to about 5000 sccm or about 1000 sccm to about 4000 sccm. A time of the gas flow during the purge sub step can be relatively short to facilitate relatively rapid deposition of material. By way of examples, a time of the gas flow during this purge sub step can be greater than 0 and less than 1 second or range from about 0.1 seconds to about 0.9 seconds or about 0.3 seconds to about 0.5 seconds. In some embodiments, the purge is performed by forming a vacuum into the reaction chamber. In other words, the reactant is pumped away from the reaction chamber so that the reaction chamber is free, or substantially free from the reactant.

Step 106 includes performing a deposition cycle, such as an ALD deposition cycle. Each deposition cycle can include introducing a second reactant to the substrate, wherein the second reactant reacts with the surface to form chemisorbed layer in the gap, and forming second active species from a third reactant that react with the chemisorbed material to form deposited layer.

The second active species is formed providing pulsed plasma power to an electrode for a plasma power period to form a plasma within the reaction chamber. The reaction of the second reactant in the vicinity of the top of the gap is at least partially inhibited by the inhibition layer. A ratio of a number of steps of forming first active species and a number of deposition cycles ranges from about 1:1 to about 1:10.

A pressure within a reaction chamber during step 106 can be the same or similar to the pressure within the reaction chamber during any of steps 102 and 104. By way of example, the pressure within the reaction chamber during step 106 can be about 1 Torr to about 5 Torr or about 2 Torr to about 4 Torr or about 2 Torr to 8 Torr.

The second reactant can be introduced to the reaction chamber to form chemisorbed material. The second reactant can include, for example, silicon. By way of examples, the second reactant can include one or more of silane amines (aminosilanes), siloxane amines and silazane amines. Alternatively, the second reactant can include a halide, such as a chloride or an iodide (e.g., a chlorosilane or an iodosilane). By way of particular example, the second reactant can be or include a silanediamine, such as N,N,N′,N′-tetraethyl silanediamine, diisopropylaminosilane, bis(diethylamino) silane, tris(dimethylamino) silane, diethylaminosilane, dipropylaminosilane, si(sec-butylamino) silane. In some embodiments, the second reactant can be or include trisilylamine ((SiH3)3N); disilylmethylamine ((SiH3)2NMe); disilylethylamine ((SiH3)2NEt); disilylisopropylamine ((SiH3)2N(iPr)); disilyl-tert-butylamine ((SiH3)2N(tBu)); diethylsilylamine (SiH3NEt2); di-tert-butylsilylamine (SiH3N(tBu)2); bis-diethylamino-silane (SiH2(NEt2)2); bis-dimethylamino-silane (SiH2(NMe2)2); bis-tertiarybutylamino-silane (SiH2(NHtBu 2); diisopropylaminosilane (SiH3N(iPr)2); tris-dimethylamino-silane (SiH(N(Me)2)3); bis-ethylmethylamino-silane (SiH2[N(Et)(Me)]2); hexakis-ethylamino-disilane (Si2(NHEt)6); tetrakis-ethylamino-silane (Si(NHEt)4), or a mixture thereof.

A pulse/flow time to introduce the second reactant to the reaction chamber can range from, for example, about greater than 0 to less than 1 second or about 0.1 to 0.5 (e.g., 0.2) seconds, or about 1 seconds.

The third reactant can be or include oxygen. By way of example, the third reactant can be or include one or more of water, hydrogen peroxide, ozone, carbon dioxide and nitrous oxide. A pulse/flow time to introduce the third reactant to the reaction chamber can range from, for example, about greater than 0 to less than 1 second or about 0.1 to 0.5 (e.g., 0.3) seconds.

During step 106, a second active species is formed from the third reactant. The second active species can react with the chemisorbed material (e.g., formed using the second reactant) to form deposited material. The second active species may, for example, react with the chemisorbed material and remove ligands from the chemisorbed material to thereby form deposited material.

The second active species can be formed using a direct plasma or a remote plasma unit. A power for producing the plasma can be, for example, between about 10 W and about 150 W, or 30 W and about 150 W, or 60 W to 120 W. In accordance with examples of the disclosure, the plasma power period is between 0.01 and 5.0 seconds. In accordance with further examples, a plasma pulse period is between about 0.01 and 0.2 msec. In accordance with additional examples, a plasma power on-time duty cycle is greater than 0 and less than 99% or between about 5 and 95%. A frequency of the pulsed plasma power can be between about 50 and 40,000 Hz or about 100 and 30,000 Hz.

Similar to step 104, step 106 can include one or more purge sub steps to purge the second and/or third reactants. During a second and/or third reactant purge sub step, excess reactant(s) and reaction byproducts, if any, can be removed from the substrate surface, for example, as described above. The purging sub steps under step 106 may be particularly desirable to mitigate any unwanted CVD reactions that might otherwise occur. In some embodiments, a flowrate of a purge gas during the second and/or third reactant purge sub steps can range from about 500 sccm to about 5000 sccm or about 1000 sccm to about 4000 sccm. A time of the gas flow during the second and/or third reactant purge sub steps can range from about greater than 0 seconds to less than 1 second or from about 0.1 seconds to about 0.5 (e.g., 0.3) seconds after introducing the second reactant and can be greater than 0 seconds to less than 1 second or from about 0.1 seconds to about 0.5 (e.g., 0.2) seconds after introducing the third reactant. Step 106 can include an additional purge—e.g., with the gas flow rates noted above for a period of about 1 to about 5 (e.g., about 2) seconds. In some embodiments, the purge is performed by forming a vacuum into the reaction chamber. In other words, the reactant is pumped away from the reaction chamber so that the reaction chamber is free, or substantially free from the reactant.

During step 112, the deposited layer from step 106 is treated in a treatment step 112. The treatment step comprises providing a third active species into the reaction chamber. The third active species is formed from the third reactant similar to the third reaction mentioned above. The third active species can react with the surface of the deposited layer to remove hydrogen from the surface and induce strong Si—O—Si crosslinking. The strong crosslinking enhances a seam free gap fill.

The third active species can be formed using an in-situ or remote plasma. A plasma power during step 104 can range from about 100 W to about 1500 W or about 150 W to about 1000 W or about 400 W to about 900 W. The plasma can be formed using a pulse time of and/or an on time for the plasma during step 104 can range from about 1 seconds to about 20 (e.g., 10) seconds or about 1 seconds to about 15 (e.g., 5) seconds or about 8 seconds to about 12 seconds or about 3 seconds to about 7 seconds.

Step 112 can include a first reactant purge sub step. During the first reactant purge sub step, excess reactant(s) and reaction byproducts, if any, may be removed from the reaction space/substrate surface, for example, by a purging gas pulse and/or vacuum generated by a pumping system. In some embodiments, the purging gas can be any inert gas, such as, without limitation, argon (Ar), nitrogen (N₂) and/or helium (He). A phase is generally considered to immediately follow another phase if a purge (i.e., purging gas pulse) or other reactant removal step intervenes. A flowrate of a purge gas during the purge sub step can range from about 500 sccm to about 5000 sccm or about 1000 sccm to about 4000 sccm. A time of the gas flow during the purge sub step can be relatively short to facilitate relatively rapid deposition of material. By way of examples, a time of the gas flow during this purge sub step can be greater than 0 and less than 1 second or range from about 0.1 seconds to about 0.9 seconds or about 0.3 seconds to about 0.5 seconds. In some embodiments, the purge is performed by forming a vacuum into the reaction chamber. In other words, the reactant is pumped away from the reaction chamber so that the reaction chamber is free, or substantially free from the reactant.

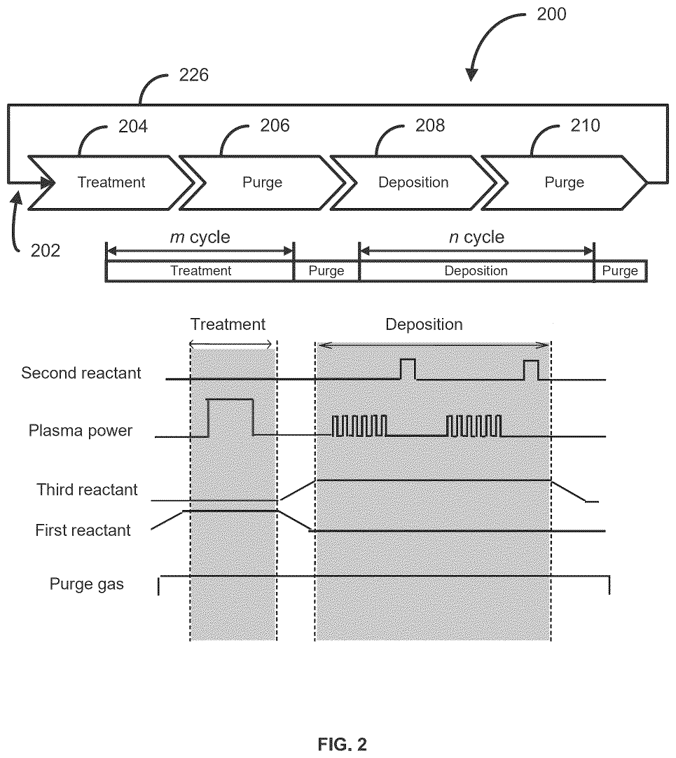

FIG. 2 illustrates a process sequence 200 in accordance with at least one embodiment of the disclosure. Process sequence 200 can be suitable for use with method of depositing a material on a surface of a substrate 100. FIG. 2 illustrates on/off sequences for gas flow and for plasma power or for provision of active species.

As illustrated, a deposition sequence 202 can include a treatment step 204, a purge step 206, a deposition cycle 208, and a final purge step 210. Treatment step 204 can be repeated m times, where m ranges from about 1 to about 5 and deposition cycle 208 can be repeated n times, where n ranges from about 1 to about 25. A ratio of men can range from, for example, 1:1, 1:3, 1:5, 1:10 or anywhere between such values. Further, deposition sequence 202 can be repeated a number of times (loop 226) until a desired thickness of material is deposited. A ratio of men can vary or remain the same for each iteration of loop 226.

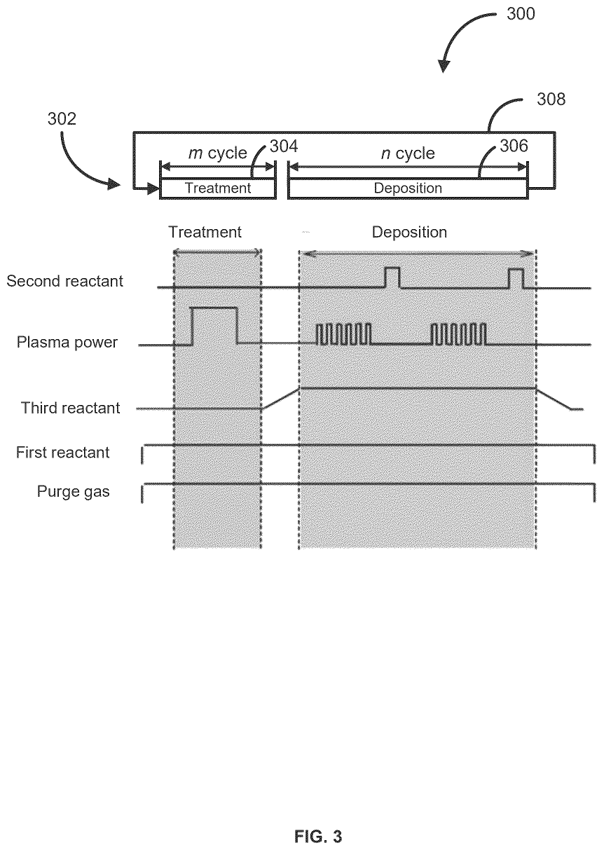

Step 204 can be the same or similar to step 104 and can follow step 102. In the illustrated example, step 204 includes an optional initial purge step 212, introduction or formation of first active species 214, and first reactant purge step 216. As illustrated, the supply of purge gas can be continuous throughout process sequence 200. A gas for forming a first active species can be provided (e.g., only) during step 216 and the plasma power for forming the first active species can be activated (e.g., only) during step 214. Alternatively, the first reactant can be supplied during one or more (e.g., all) of steps 212-224 and 210, as described in more detail in connection with FIG. 3. Similarly, a third reactant can be supplied during one or more of steps 214-224 and 210, and only activated during step 222. Step 216 can be the same or similar to first reactant purge step described above.

During step 206, another first reactant purge step can be used to facilitate removal of any unwanted material remaining from step 204. A flowrate of a purge gas during step 206 can be the same as the first purge gas flowrate described above. A time for step 206 can range from about 0.1 to about 10 seconds or about 0.2 to about 2 seconds.

Step 208 can be the same or similar to step 106, described above. As illustrated, each deposition cycle can include introduction of a second reactant (step 218), a second reactant purge (step 220), forming second active species from a third reactant (step 222), and a third reactant purge (step 224). Steps 218-224 can be the same or similar to step 106 described above.

Process sequence 200 can include a final purge step 210. The flowrate of a purge gas during step 210 can be the same or similar to third reactant purge sub step described above. A time for step 210 can range from about 0.1 to about 10 seconds or about 0.2 to about 5 seconds.

FIG. 3 illustrates another process sequence 300 in accordance with at least one embodiment of the disclosure. Method 100 can use process sequence 300 for depositing material on a surface of a substrate. Process sequence 300 is similar to process sequence 200, except process sequence 300 includes fewer purge steps, and includes a continuous flow of a first reactant. The continuous flow of the first reactant is thought to contribute to more stable process environment and to improve uniformity (e.g., composition and/or thickness) of the material deposited onto the substrate surface.

Similar to process sequence 200, process sequence 300 includes a deposition sequence 302 that includes a treatment step 304 and a deposition cycle/step 306. Unlike process sequence 200, process sequence 300 does not include a purge step 206 or a final purge 210. This allows process sequence 300 to be relatively short, which, in turn, allows for relatively rapid deposition of high-quality deposited material and high through-put, which can be used to, for example, fill a gap within a substrate surface. Treatment step 304 can be repeated m times, where m ranges from about 1 to about 5 and deposition cycle 208 can be repeated n times, where n ranges from about 1 to about 2. A ratio of men can range from, for example, 1:1, 1:3, 1:5, 1:10 or anywhere between such values. Further, deposition sequence 302 can be repeated a number of times (loop 308) until a desired thickness of material is deposited. A ratio of men can vary or remain the same for each iteration of loop 308.

As illustrated in FIG. 3, process sequence 300 can begin with forming a first active species from a first reactant step 310, wherein a first reactant and a purge gas are continuously provided to a reaction chamber. During step 310, a first reactant may be activated by RF power to form first active species, as described above in connection with FIG. 1. A time for the plasma activation of the first reactant can range from greater than 0.1 seconds to about 10 (e.g., 5) seconds or about 0.2 seconds to about 0.5 seconds. Plasma ignition time is also thought to be an important factor for seamless fill of deposited material in a gap, and can depend on various factors, including an aspect ratio of a feature and a ration of min as defined above. During step 312, purge gas and first reactant are allowed to flow through the reaction chamber.

During deposition cycle 306, a second reactant can be introduced to the reaction chamber. A flowrate of the second reactant and a pulse time for the second reactant can be the same or similar to the flowrate of the second reactant during steps 106 and 218, described above in connection with FIGS. 1 and 2. The second reactant can then be purged during step 316 by allowing the first reactant, the purge gas, and optionally the third reactant to continue to flow, as illustrated. When the third reactant is allowed to flow for additional steps (e.g., steps 312-316 and 320 in addition to step 318), the third reactant can be activated for a time period in step 318, such that second active species formed from the third reactant that react with the chemisorbed material to form deposited material is formed (e.g., only) during step 318. Alternatively, the third reactants can be flowed only during step 318.

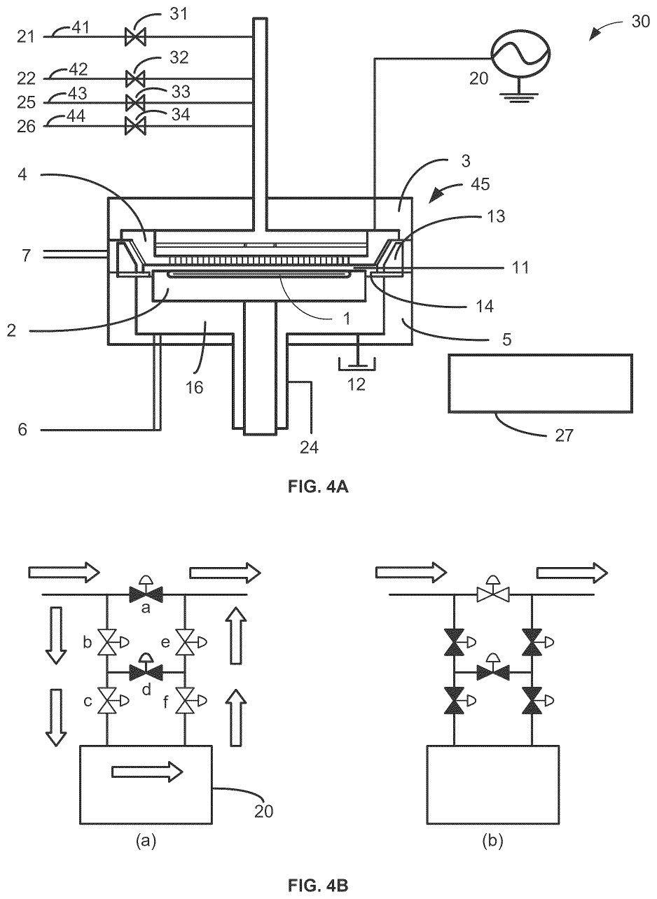

FIG. 4A and FIG. 4B illustrate a semiconductor processing apparatus 30 in accordance with exemplary embodiments of the disclosure. Semiconductor processing apparatus 30 includes one or more reaction chambers 3 for accommodating a substrate that can include a surface that can include a gap formed therein; a first source 21 for a first reactant in gas communication via a first valve 31 with one of the reaction chambers; a second source 22 for a second reactant in gas communication via a second valve 32 with one of the reaction chambers; a third source 25 for a third reactant in gas communication via a third valve 33 with one of the reaction chambers; an optional fourth source 26 (e.g., for a purge or carrier gas) in gas communication via a fourth valve 34 with one of the reaction chambers; and a controller 27 operably connected to the first, second, third, and optionally fourth gas valves and configured and programmed to control: forming first active species from a first reactant to modify a surface of the substrate and performing one or more deposition cycles to deposit material. The modified surface acts as an inhibition layer in a vicinity of a top of the gap on the substrate. Each deposition cycle comprises introducing a second reactant to the reaction chamber, wherein the second reactant reacts with the surface of the substrate to form a chemisorbed layer in the gap; and forming a second active species from a third reactant that reacts with the chemisorbed layer to form a deposited layer. The second active species is formed providing pulsed plasma power to an electrode for a plasma power period to form a plasma within the reaction chamber. The reaction of the second reactant in the vicinity of the top of the gap is at least partially inhibited by the inhibition layer. A ratio of a number of steps of forming first active species and a number of deposition cycles ranges from about 1:1 to about 1:10. The fourth gas can be introduced with any of the first, second, and/or third reactants, and/or can be used as a purge gas as described herein. Although not illustrated, semiconductor processing apparatus 30 can include additional sources and additional components, such as those typically found on semiconductor processing apparatus.

Optionally, the controller is further configured and programmed to control forming a third active species from the third reactant to treat the deposited layer.

Optionally, semiconductor processing apparatus 30 is provided with a heater to activate the reactions by elevating the temperature of one or more of the substrate, the first, second and third reactants.

Semiconductor processing apparatus 30 may be provided with a radiofrequency source operably connected with the controller constructed and arranged to produce a plasma of at least one of the first, second and/or third reactant or combination of thereof.

Process steps with a plasma may be performed using semiconductor processing apparatus 30, desirably in conjunction with controls programmed to conduct the sequences described herein, usable in at least some embodiments of the present disclosure. In the apparatus illustrated in FIG. 4A, by providing a pair of electrically conductive flat-plate electrodes 4, 2 in parallel and facing each other in the interior 11 (reaction zone) of reaction chamber 3, applying RF power (e.g., 13.56 MHz or 27 MHz or 12.9 MHz or 430 kHz) from a power source 20 to one side, and electrically grounding the other side 12, a plasma is excited between the electrodes.

A temperature regulator can be provided in a lower stage 2 (the lower electrode), and a temperature of substrate 1 placed thereon can be kept at a relatively constant temperature. The upper electrode 4 can serve as a shower plate as well, and reactant gas (and optionally an inert gas, such as a noble gas) and/or purge gasses can be introduced into the reaction chamber 3 through gas lines 41-44, respectively, and through the shower plate 4.

Additionally, in the reaction chamber 3, a circular duct 13 with an exhaust line 7 is provided, through which gas in the interior 11 of the reaction chamber 3 is exhausted. Additionally, a lower portion 5 of the reaction chamber 3—e.g., disposed below an upper portion 45 of the reaction chamber 3—is provided with a seal gas line 24 to introduce seal gas into the interior 11 of the reaction chamber 3 via the lower space 16 of the low portion 5 of the reaction chamber 3, wherein a separation plate 14 for separating the reaction zone between an upper electrode 4 and a lower stage 2 and the lower space 16 is provided (a gate valve through which a wafer is transferred into or from the lower portion of the reaction chamber 3 is omitted from this figure). The lower portion of the reaction chamber 5 is also provided with an exhaust line 6. In some embodiments, the deposition of a multi-element film and a surface treatment (e.g., steps 104-108) are performed in the same reaction space, so that all the steps can continuously be conducted without exposing the substrate to air or other oxygen-containing atmosphere. In some embodiments, a remote plasma unit can be used for exciting a gas—e.g., from one or more of sources 21, 22, 25, and/or 26.

In some embodiments, in the apparatus depicted in FIG. 4A, a system of switching flow of an inactive gas and flow of a precursor or reactant gas is illustrated in FIG. 4B; this system can be used to introduce the precursor or reactant gas in pulses without substantially fluctuating pressure of the reaction chamber. FIG. 4B illustrates a precursor supply system using a flow-pass system (FPS) according to an embodiment of the present disclosure (black valves indicate that the valves are closed). As shown in (a) in FIG. 4B, when feeding a precursor to a reaction chamber (not shown), first, a carrier gas such as Ar (or He) flows through a gas line with valves b and c, and then enters a bottle (reservoir) 20. The carrier gas flows out from the bottle 20 while carrying a precursor gas in an amount corresponding to a vapor pressure inside the bottle 20 and flows through a gas line with valves f and e, and is then fed to the reaction chamber together with the precursor. In this case, valves a and d are closed. When feeding only the carrier gas (e.g., noble gas) to the reaction chamber, as shown in (b) in FIG. 4B, the carrier gas flows through the gas line with the valve while bypassing the bottle 20. In this case, valves b, c, d, e, and f are closed. A reactant may be provided with the aid of a carrier gas.

A plasma for deposition may be generated in situ, for example, using one or more gasses that flow—e.g., continuously throughout the deposition cycle. In other embodiments, a plasma may be additionally or alternatively generated remotely and active species provided to the reaction chamber.

In some embodiments, a multi chamber reactor (more than two sections or compartments for processing wafers disposed closely to each other) can be used, wherein a reactant gas and an inert gas, such as a noble gas, can be supplied through a shared line, whereas a precursor gas can be supplied through unshared lines. Or a precursor gas can be supplied through shared lines.

An apparatus can include one or more controller(s), such as controller 27, programmed or otherwise configured to cause the deposition processes described herein to be conducted. The controller(s) can be communicated with the various power sources, heating systems, pumps, robotics, and gas flow controllers or valves of the reactor.

The illustrations presented herein are not meant to be actual views of any particular material, structure, or device, but are merely idealized representations that are used to describe embodiments of the disclosure.

The particular implementations shown and described are illustrative of the invention are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method for filling a gap, the method comprising the steps of:
providing the substrate with a gap in a reaction chamber;
forming first active species from a first reactant for forming an inhibition layer in a vicinity of a top of the gap; and
performing one or more deposition cycles to deposit a material into the gap, wherein each deposition cycle comprises:
introducing a second reactant to the reaction chamber, wherein the second reactant reacts with the surface of the substrate to form a chemisorbed layer in the gap; and
forming a second active species from a third reactant that reacts with the chemisorbed layer to form a deposited layer,
wherein the second active species is formed providing pulsed plasma power to an electrode for a plasma power period to form a plasma within the reaction chamber,
wherein the reaction of the second reactant in the vicinity of the top of the gap is at least partially inhibited by the inhibition layer, and
wherein a ratio of a number of steps of forming first active species and a number of deposition cycles ranges from about 1:1 to about 1:10.

2. The method according to claim 1, further comprising forming a third active species from the third reactant to treat the deposited layer.

3. The method according to claim 1, wherein the ratio of a number of steps of forming a first active species and a number of deposition cycles ranges from about 1:1 to about 1:5.

4. The method according to claim 1, wherein the deposited layer comprises silicon.

5. The method according to claim 4, wherein the deposited layer comprises silicon oxide.

6. The method according to claim 1, wherein the first active species removes one of more of hydrogen or hydroxyl group form the surface of the substrate.

7. The method according to claim 1, wherein a flow of the first reactant is continuous during the step of forming first active species and the step of performing one or more deposition cycles.

8. The method according to claim 7, wherein the step of forming first active species does not include a purge step.

9. The method according to claim 1, further comprising a step of providing an inert gas to the reaction chamber.

10. The method of claim 9, wherein the inert gas is provided continuously during the steps of forming first active species and performing one or more deposition cycles.

11. The method according to claim 1, wherein the first reactant comprises nitrogen.

12. The method according to claim 11, wherein the first reactant comprises one or more of N₂, NH₃, NO, N₂O, NO₂, NF₃.

13. The method according to claim 12, wherein the first reactant comprises NH₃.

14. The method according to claim 1, wherein the second reactant comprises silicon.

15. The method according to claim 14, wherein the second reactant comprises silane, aminosilane, siloxane amine and silazane amine.

16. The method according to claim 1, wherein the third reactant comprises oxygen.

17. The method according to claim 16, wherein the third reactant comprises one or more of water, oxygen, hydrogen peroxide, ozone, carbon dioxide or nitrous oxide.

18. The method according to claim 1, wherein a temperature of a substrate support within the reaction chamber is less than 600° C.

19. The method according to claim 1, wherein the steps of forming first active species and performing one or more deposition cycles are repeated until the gap is filled with the deposited material.

20. The method according to claim 1, wherein the growth of the deposited film is at least two times slower at vicinity of the top of the gap than at the bottom of the gap.

21. A semiconductor processing apparatus comprising:
one or more reaction chambers for accommodating a substrate comprising a gap;
a first source for a first reactant in gas communication via a first valve with one of the reaction chambers;
a second source for a second reactant in gas communication via a second valve with one of the reaction chambers;
a third source for a third reactant in gas communication via a third valve with one of the reaction chambers; and
a controller operably connected to the first, second, and third gas valves and configured and programmed to control:
forming first active species from a first reactant for forming an inhibition layer in a vicinity of a top of the gap; and
performing one or more deposition cycles to deposit a material into the gap, wherein each deposition cycle comprises:
introducing a second reactant to the reaction chamber, wherein the second reactant reacts with the surface of the substrate to form a chemisorbed layer in the gap; and
forming a second active species from a third reactant that reacts with the chemisorbed layer to form a deposited layer,
wherein the second active species is formed providing pulsed plasma power to an electrode for a plasma power period to form a plasma within the reaction chamber,
wherein the reaction of the second reactant in the vicinity of the top of the gap is at least partially inhibited by the inhibition layer, and
wherein a ratio of a number of steps of forming first active species and a number of deposition cycles ranges from about 1:1 to about 1:10.

22. The semiconductor apparatus of claim 21, wherein the controller is further configured and programmed to control forming a third active species from the third reactant to treat the deposited layer.
